(19) United States
(12) Patent Application Publication
(10) Pub. No.: US 2007/0090406 A1
(43) Pub. Date: Apr. 26, 2007

(54) STRUCTURE AND METHOD FOR MANUFACTURING HIGH PERFORMANCE AND LOW LEAKAGE FIELD EFFECT TRANSISTOR

(75) Inventors: Huilong Zhu, Poughkeepsie, NY (US); Kangguo Cheng, Beacon, NY (US)

Correspondence Address: OHLANDT, GREELEY, RUGGIERO & PERLE, LLP, ONE LANDMARK SQUARE, 10TH FLOOR, STAMFORD, CT, 06901, US

(73) Assignee: INTERNATIONAL BUSINESS MACHINES CORPORATION, Armonk, NY (US)

(21) Appl. No.: 11/163,647

(22) Filed: Oct. 26, 2005

(51) Int. Cl. H01L 29/76; H01L 29/745

(52) U.S. Cl. 257/213

(57) ABSTRACT

There is provided a field effect transistor (FET) including a source side semiconductor; a drain side semiconductor; and a gate. The source side semiconductor is made of a high mobility semiconductor material, and the drain side semiconductor is made of a low leakage semiconductor material. In one embodiment, the FET is a Metal-Oxide-Semiconductor Field Effect Transistor (MOSFET). There is also provided a method for manufacturing the FET.

### BACKGROUND OF THE INVENTION

1. Field of the Invention

The present invention relates to semiconductor devices. More particularly, the present invention relates to metal-oxide-semiconductor field effect transistors.

2. Description of the Related Art

MOSFET (Metal-Oxide-Semiconductor Field Effect Transistor) transistors consistently pose challenges as they are scaled down in size. Even with aggressive scaling of the MOSFET channel to lengths of approximately 25 nm, mobility continues to be a critical parameter. Also, charge transport in the channel remains far from ballistic, so that electron or hole scattering is observed when electrons or holes transfer from the source to the drain. This is because scaling degrades mobility by increasing channel doping (halo doping) and vertical electric fields. As gate length is scaled smaller and smaller, short channel effects become more pronounced and power consumption increases.

To improve the performance of a MOSFET device, germanium (Ge) or silicon germanium (SiGe) can be used as a semiconductor material in the channel of the MOSFET. However, although Ge or SiGe field effect transistors (FET) exhibit high performance or high mobility of electron and/or hole, such FET's also exhibit high junction leakage, which increases the stand-by power of VLSI and computer chips. Thus, it is difficult to improve device performance while stand-by power consumption remains significant.

### SUMMARY OF THE INVENTION

It is an object of the present invention to provide a field effect transistor (FET) having improved characteristics at small scales.

It is another object of the present invention to provide a FET transistor having high mobility at small scales.

It is yet another object of the present invention to provide a FET transistor having reduced short channel effects and reduced power consumption.

It is a further object of the present invention to provide a method of manufacturing a FET transistor having high mobility, reduced short channel effects, and reduced power consumption at small scales.

These and other objects and advantages of the present invention are achieved by a field effect transistor (FET) including a source side semiconductor, a drain side semiconductor, and a gate. The source side semiconductor is made of a high mobility semiconductor material, and the drain side semiconductor is made of a low leakage semiconductor material. In one embodiment, the FET is a Metal-Oxide-Semiconductor Field Effect Transistor (MOSFET). There is also provided a method for manufacturing the FET.

### BRIEF DESCRIPTION OF THE DRAWINGS

FIG. 1 is a cross-sectional view of an embodiment of a MOSFET of the present invention.

FIG. 2A is a cross-sectional view of a first step of a method of manufacturing an embodiment of the MOSFET of the present invention.

FIG. 2B is a cross-sectional view of a second step of the method of manufacturing an embodiment of the MOSFET of the present invention.

FIG. 2C is a cross-sectional view of a third step of the method of manufacturing an embodiment of the MOSFET of the present invention.

FIG. 2D is a cross-sectional view of a fourth step of the method of manufacturing an embodiment of the MOSFET of the present invention.

FIG. 2E is a cross-sectional view of a fifth step of the method of manufacturing an embodiment of the MOSFET of the present invention.

FIG. 2F is a cross-sectional view of a sixth step of the method of manufacturing an embodiment of the MOSFET of the present invention.

FIG. 2G is a cross-sectional view of a seventh step of the method of manufacturing an embodiment of the MOSFET of the present invention.

FIG. 2H is a cross-sectional view of an eighth step of the method of manufacturing an embodiment of the MOSFET of the present invention.

FIG. 2I is a cross-sectional view of a ninth step of the method of manufacturing an embodiment of the MOSFET of the present invention.

FIG. 2J is a cross-sectional view of a tenth step of the method of manufacturing an embodiment of the MOSFET of the present invention.

FIG. 2K is a cross-sectional view of an eleventh step of the method of manufacturing an embodiment of the MOSFET of the present invention.

FIG. 2L is a cross-sectional view of a twelfth step of the method of manufacturing an embodiment of the MOSFET of the present invention.

FIG. 2M is a cross-sectional view of a thirteenth step of the method of manufacturing an embodiment of the MOSFET of the present invention.

FIG. 2N is a cross-sectional view of a MOSFET manufactured according to the method shown in FIGS. 2A-2M.

FIG. 3 is a cross-sectional view of another embodiment of the MOSFET of the present invention.

### DESCRIPTION OF THE INVENTION

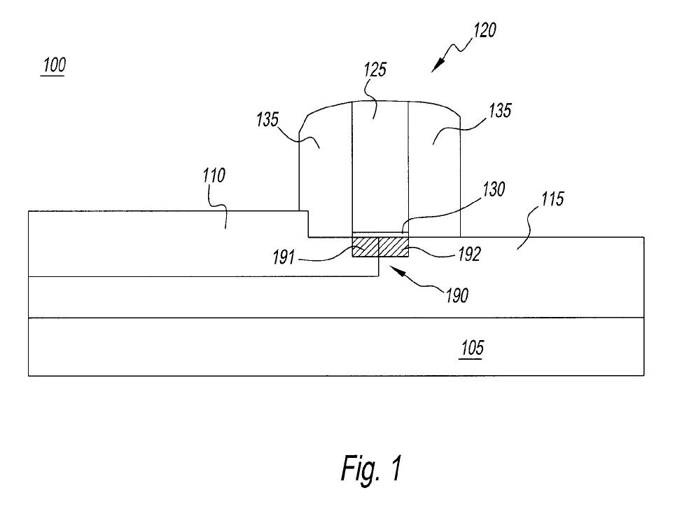

Referring to the drawings and, in particular, FIG. 1, there is provided a first embodiment of the Field Effect Transistor (FET) of the present invention generally represented by reference numeral 100. The FET is preferably a Metal-Oxide-Semiconductor Field Effect Transistor (MOSFET). However, the FET may also be a Metal-insulator-Semiconductor Field Effect Transistor. The FET transistor can be a n-type FET transistor or a p-type FET transistor. In another embodiment, the FET is an asymmetrical FET.

In another embodiment, the FET transistor is a short-channel MOSFET transistor. In a preferred embodiment, the short-channel MOSFET has a channel of a length preferably between about 5 nm and 100 nm.

Referring again to FIG. 1, MOSFET 100 includes an insulator 105, a source 110, a drain 115, and a gate 120. Gate 120 includes a gate conductor 125, a gate dielectric 130, and a gate insulator 135. MOSFET 100 also includes a channel region 190, that further includes a first channel portion 191 and a second channel portion 192. First channel portion 191 is located in an area of source 110 under gate 120, and second channel portion 192 is located in an area of drain 115 under gate 120.

Insulator 105 and gate insulator 135 are made from any suitable insulating materials known for semiconductor devices, such as nitrides and oxides. Insulator 105 may be any suitable material, including for example, Ge, SiGe, SiGeC, Ge alloys, GaAs, InAs, InP, and semiconductors-on-insulator layers. Gate conductor 125 is made from a suitable conductive material such as a metal or polycrystalline silicon (poly-Si). Gate dielectric 130 is preferably made from a suitable dielectric material including oxides such as SiO₂, HfO₂, ZrO₂, Al₂O₃, TiO₂, La₂O₃, SrTiO₃, LaAlO₃, or any combinations thereof. In another embodiment, gate dielectric 130 preferably has a dielectric constant between 5 and 40 times higher than silicon dioxide.

In one embodiment, source 110 and first channel portion 191 are made from a semiconductor material having high mobility characteristics. Such materials include silicon germanium (SiGe) and germanium (Ge), both of which exhibit high electron mobility as compared to other semiconductors such as silicon. In another embodiment, source 110 is made from SiGe that has approximately 10% to approximately 50% germanium. Other high mobility semiconductor materials may be used to create source 110, such as SiGeC, Ge alloys, GaAs, InAs, InP, and other III-V or II-VI compound semiconductors.

In another embodiment, source 110 is made from a material that has electron mobility between 1.1 and 2 times that of pure silicon.

In yet another embodiment, drain 115 and second channel portion 192 are made from a semiconductor material having low leakage characteristics. Such materials include silicon (Si) and Silicon carbide (SiC), both of which exhibit low current leakage through gate dielectric 130. Other materials suitable for creating drain 115 include GaAs, InAs, InP, as well as other III-V or II-VI compound semiconductors

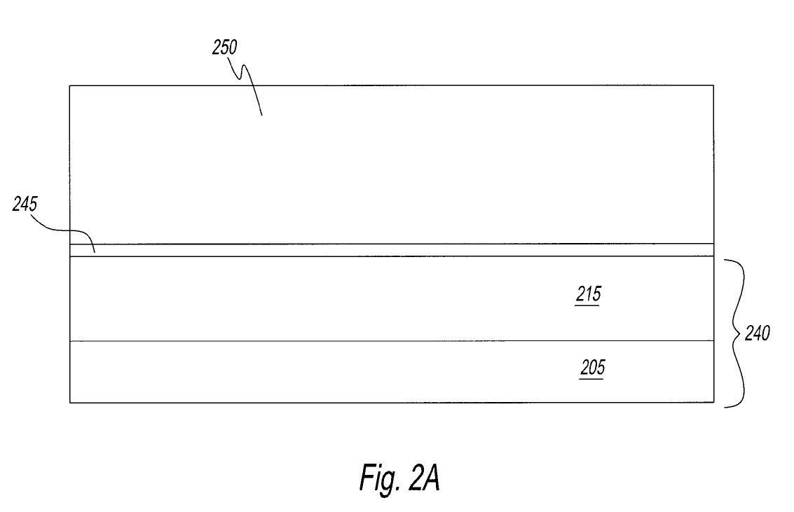

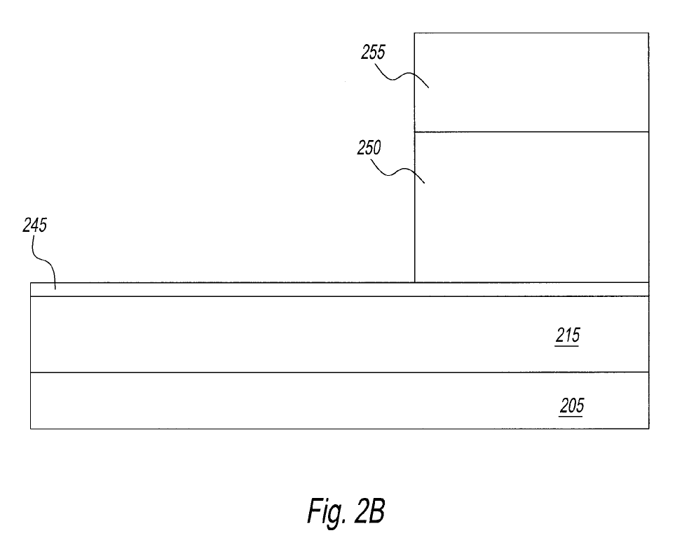

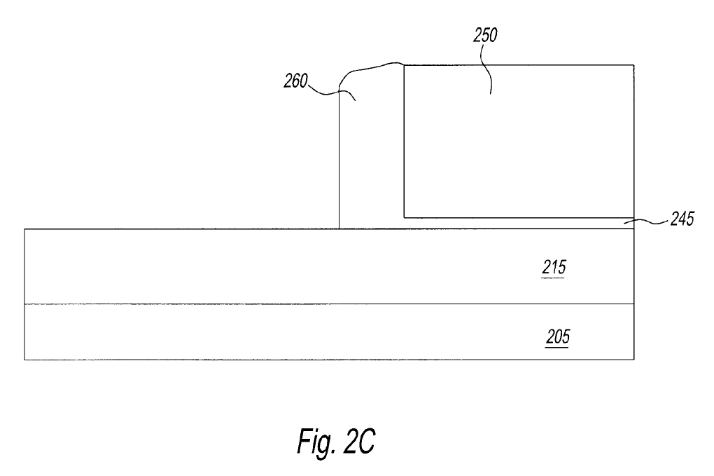

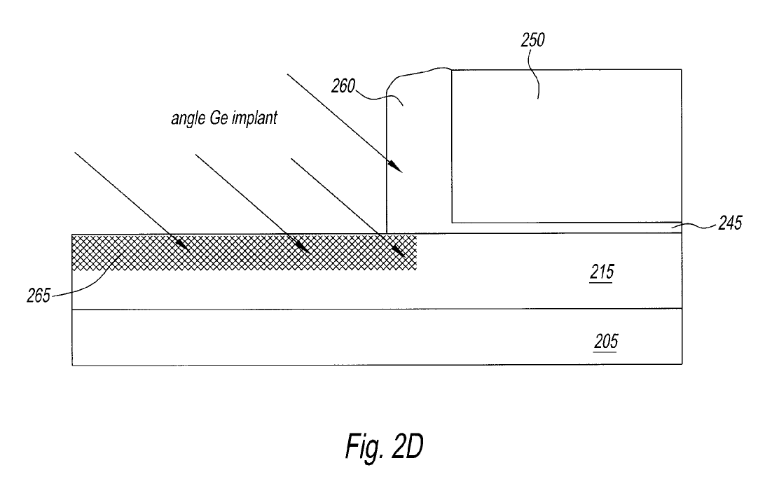

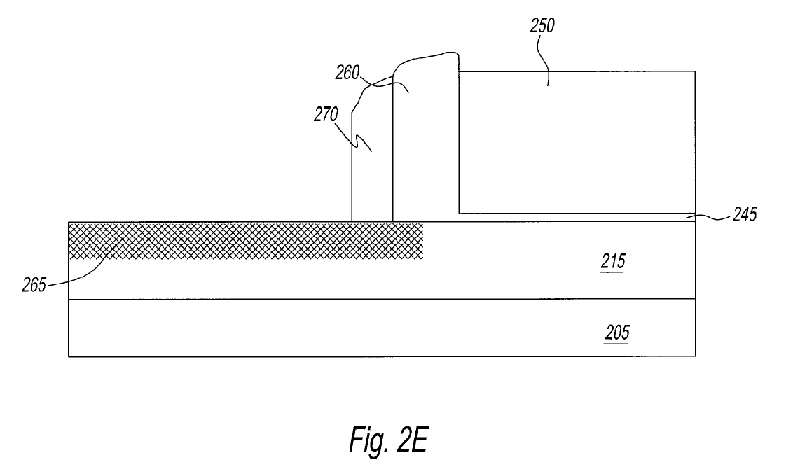

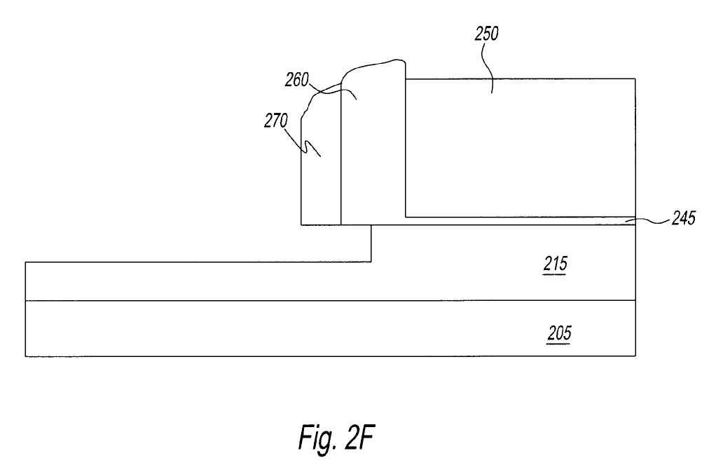

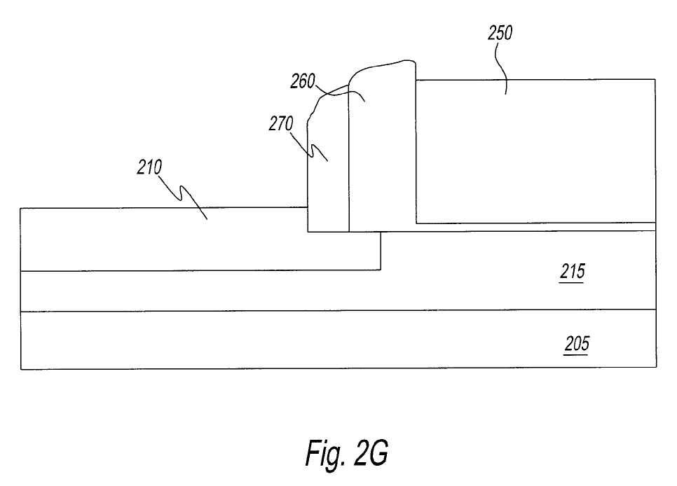

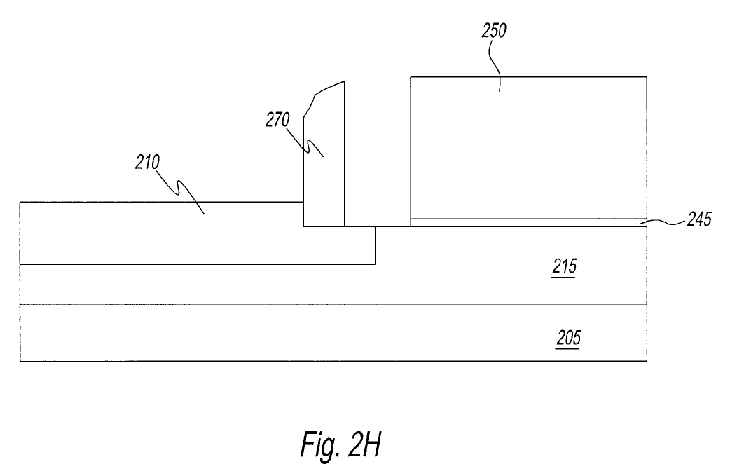

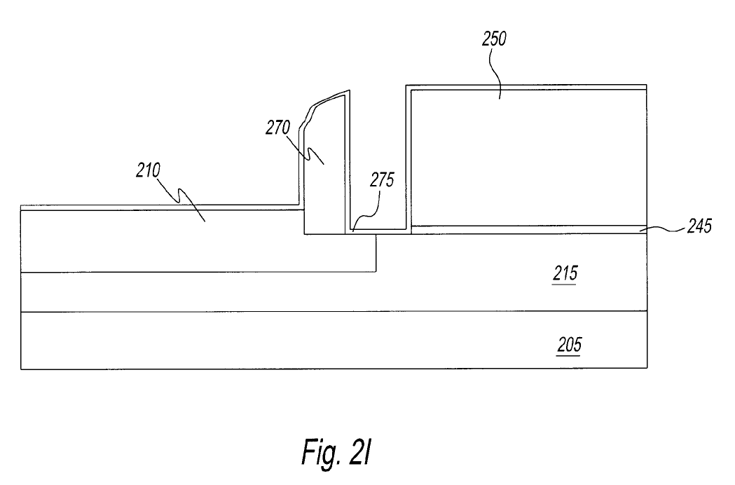

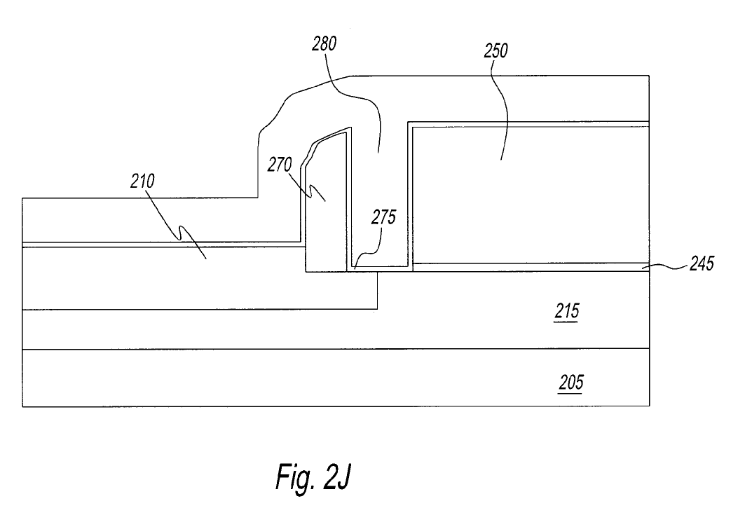

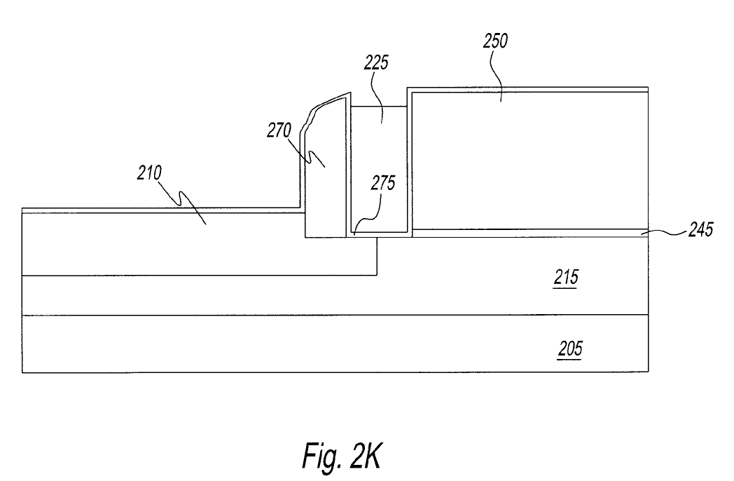

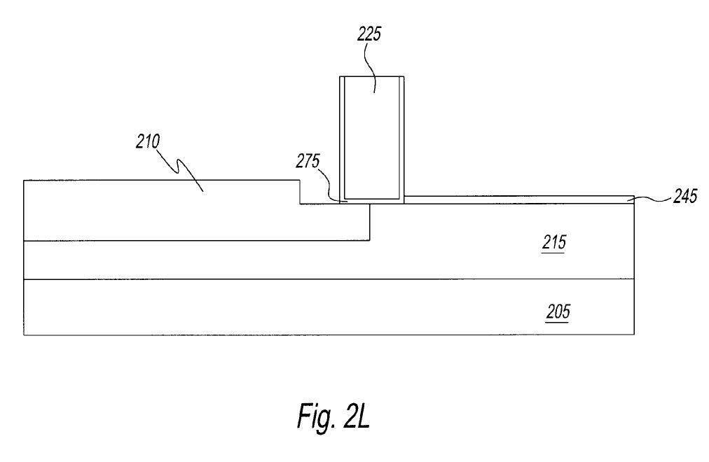

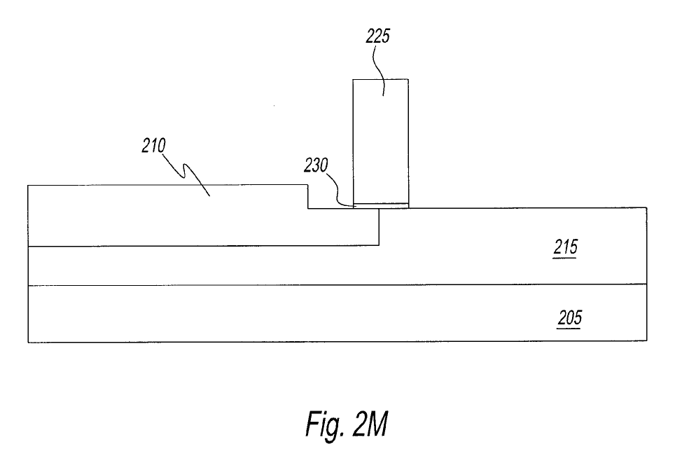

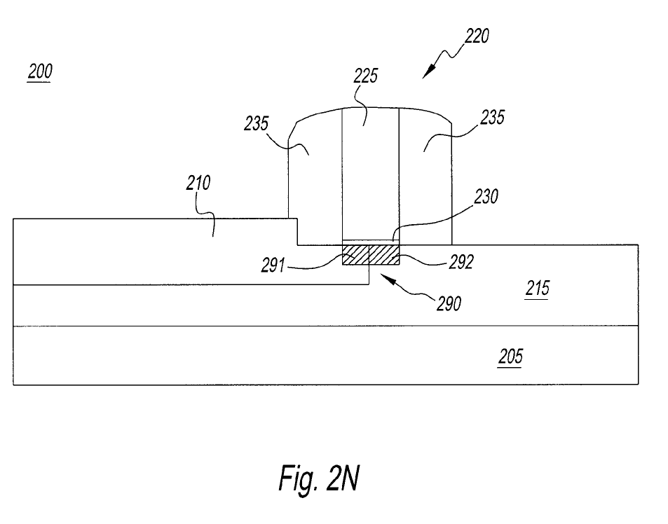

Referring to FIGS. 2A-2N, a MOSFET 200, similar to MOSFET 100, is manufactured on a Silicon-On-Insulator (SOI) substrate 240, as shown in FIG. 2A. SOI substrate 240 includes a silicon layer having a thin layer of silicon oxide (SiO₂), i.e., buried oxide 205, buried within. MOSFET 100 is built on the silicon layer 215 on top of buried oxide 205.

A method utilized in manufacturing MOSFET 200 is shown in FIGS. 2A-2M. The completed MOSFET 200 is shown in FIG. 2N, and is similar in structure to MOSFET 100.

Referring to FIG. 2A, a layer of oxide 245 is first deposited on SOI substrate 240, and a layer of nitride 250 is deposited on oxide layer 245. In one embodiment, oxide layer 245 has a deposited thickness of approximately 5 nm to approximately 10 nm, and nitride layer 250 has a deposited thickness of approximately 100 nm to approximately 150 nm.

Referring to FIG. 2B, a photoresist mask 255 is applied on nitride layer 250, and a portion of nitride layer 250 is removed. Removal of nitride layer 250 can be accomplished by reactive ion etching (RIE). Referring to FIG. 2C, oxide is deposited and subsequently etched, e.g., by RIE, to form oxide spacer 260 at a side wall of nitride layer 250.

Referring to FIG. 2D, a portion of silicon layer 215 is doped with germanium (Ge), preferably by angle Ge implantation to form Ge doped region 265. Angle Ge implantation may be performed, for example, with an implant energy between about 10 keV and about 80 keV, a dose of between about 2e14 and about 5e15 atoms/cmˆ2, and a tilt angle of between about 20 degrees and about 60 degrees from the normal. Referring to FIG. 2E, a nitride spacer 270 is formed by deposition and etching. The deposition thickness of nitride spacer 270 is preferably approximately 70 nm.

Referring to FIG. 2F, Ge doped region 265 is etched from silicon layer 215. Referring to FIG. 2G, a layer of high mobility semiconductor material, i.e., source layer 210 is deposited on the exposed portion of silicon layer 215 that forms drain layer 215, to form source 210 and first channel portion 291. In one embodiment, source layer 210 is a layer of SiGe, which has a higher mobility than drain layer 215, which in this embodiment, is made of silicon. In another embodiment, source layer 210 is epitaxially grown on drain layer 215.

Referring to FIG. 2H, oxide spacer 260 is etched away, i.e., removed by etching. Referring to FIG. 2I, a dielectric layer 275 is deposited on source layer 210, nitride spacer 270, drain layer 215 and nitride layer 250. Dielectric layer will form part of gate 220 (see FIG. 2N).

Referring to FIG. 2J, a conductive layer 280 is deposited over dielectric layer 275, and fills the gap between nitride spacer 270 and nitride layer 250. Conductive layer 280 is preferably a metal or polycrystalline silicon (poly-Si) layer. Preferably, the poly-Si material is n-type doped for field effect transistors with a n-type channel (nFET) and p-type doped for field effect transistors with a p-type channel (pFET). Referring to FIG. 2K, conductive layer 280 is partially etched away to form gate conductor 225 for gate 220 (see FIG. 2N).

Referring to FIG. 2L, nitride spacer 270, nitride layer 250 and a portion of dielectric layer 275 are etched away. Referring to FIG. 2M, oxide layer 245 is removed by etching. Also, a further portion of dielectric layer 275 is etched away to form gate dielectric 230.

Referring to FIG. 2N, MOSFET 200 is completed by the addition of insulators 235. Thus, MOSFET 200 includes buried oxide 205 that acts as a substrate, source 210, drain 215, and gate 220. Gate 220 includes conductor 225, dielectric 230 and insulators 235. Preferably, insulators 235 are made from a nitride, however other materials can be used.

MOSFET 200 also includes a channel region 290, that further includes first channel portion 291 and a second channel portion 292. First channel portion 291 is located in an area of source 210 under gate 220, and second channel portion 292 is located in an area of drain 215 under gate 220.

The final steps of forming insulators 235 can be accomplished by any suitable process. For example, a conventional process may be used to form insulator 235 by depositing a nitride layer and anisotropically performing RIE to form a nitride spacer. In one embodiment, angle halo implantation is utilized. Other processes may include extension implant, nitride spacer formation, source/drain implantation, and SD RTA to activate dopants in the device.

Deposition of various layers described above, such as oxide layer 245 and nitride layer 250, can be accomplished in any known manner suitable for constructing semiconductor devices. Examples of suitable deposition techniques include chemical vapor deposition (CVD), plasma-enhanced CVD (PECVD), and high density plasma deposition (HDP). In addition, etching of various layers described above can be accomplished by any suitable known method. In one embodiment, etching is accomplished by a reactive ion etching technique.

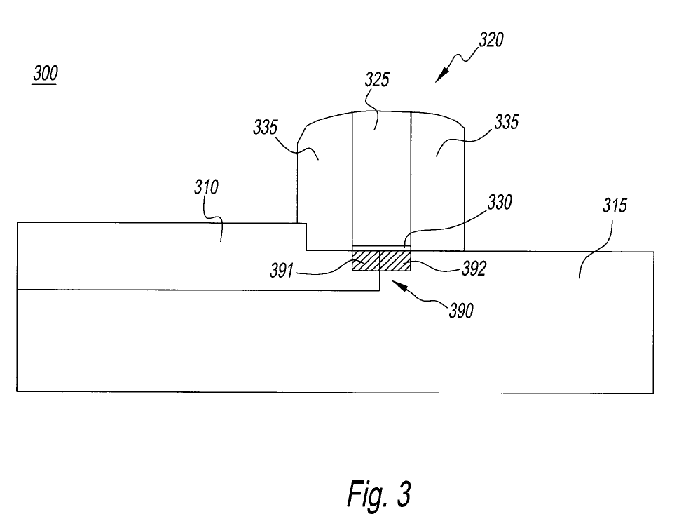

Referring to FIG. 3, in one embodiment, MOSFET 300 is manufactured on a bulk wafer, such as a silicon substrate. MOSFET 300 includes a source 310, a drain 315, and a gate 320. Gate 320 includes gate conductor 325, gate dielectric 330, and gate insulator 335.

MOSFET 300 also includes a channel region 390, that further includes first channel portion 391 and a second channel portion 392. First channel portion 391 is located in an area of source 310 under gate 320, and second channel portion 392 is located in an area of drain 315 under gate 320.

In one embodiment, source 310 and first channel portion 391 are made from a semiconductor material having high mobility characteristics, such as silicon germanium (SiGe) and germanium, Ge. Drain 315 and second channel portion 392 are made from a semiconductor material having low leakage characteristics.

The exemplary embodiments of the MOSFET device of the present invention are provided to demonstrate the aspects of the present invention. The present invention is not limited to the MOSFET transistors described above. Variations to the configuration, such as the size and position of the gate, source and drain, fall within the scope of the invention.

The MOSFET devices of the present invention exhibit superior characteristics as compared to prior art MOSFET devices. This is particularly true as MOSFET geometries are scaled down. For example, the MOSFET device of the present invention exhibits superior mobility characteristics, reduces short channel effects and reduces power consumption. Additional advantages of the MOSFET device of the present invention include reduced leakage of current through the p-n junction, as well as reduced subthreshold leakage. Reduction of subthreshold leakage also contributes to the device's reduced power consumption.

For example, the MOSFET device of the present invention exhibits high mobility even as the MOSFET channel is scaled to lengths approaching and equal to 25 nm. This is because scaling degrades mobility by increasing channel doping (halo doping) and vertical electric fields. As gate length is scaled smaller and smaller, short channel effects and power consumption become more pronounced.

It should be understood that various alternatives, combinations and modifications of the teachings described herein could be devised by those skilled in the art. The present invention is intended to embrace all such alternatives, modifications and variances that fall within the scope of the appended claims.

What is claimed is:

1. A field effect transistor (FET), comprising:
a source semiconductor having a first portion of a channel;
a drain semiconductor having a second portion of said channel; and
a gate,
wherein said source semiconductor is made of a high mobility semiconductor material, and wherein said drain semiconductor is made of a low leakage semiconductor material.

2. The FET of claim 1, wherein said FET is selected from the group consisting of a Metal-Oxide-Semiconductor Field Effect Transistor, a Metal-insulator-Semiconductor Field Effect Transistor, and a combination thereof.

3. The FET of claim 1, wherein said high mobility semiconductor material is selected from the group consisting of Ge, SiGe, SiGeC, Ge alloys, GaAs, InAs, InP, group III-V compound semiconductors, and group II-VI compound semiconductors.

4. The FET of claim 3, wherein said high mobility semiconductor material has about 10% to about 50% Ge.

5. The FET of claim 1, wherein said low leakage semiconductor material is selected from the group consisting of Si, SiC, GaAs, InAs, InP, group III-V compound semiconductors, and group II-VI compound semiconductors.

6. The FET of claim 1, wherein said FET is a short-channel MOSFET.

7. The FET of claim 6, wherein said short-channel MOSFET has a channel with a length between about 5 nm and about 100 nm.

8. The FET of claim 1, wherein said FET is built on a substrate selected from the group consisting of a semiconductor substrate of Ge, SiGe, SiGeC, Ge alloys, GaAs, InAs, InP, and a semiconductor-on-insulator.

9. The FET of claim 1, wherein said FET is selected from the group consisting of a n-type FET and p-type FET.

10. The FET of claim 1, wherein said FET is an asymmetrical FET.

11. A method of manufacturing a field effect transistor (FET), comprising the steps of:
forming a drain semiconductor having a first portion of a channel;
forming a source semiconductor having a second portion of a channel; and
forming a gate proximate to said drain semiconductor and said source semiconductor,
wherein said source semiconductor is made of a high mobility semiconductor material, and wherein said drain semiconductor is made of a low leakage semiconductor material.

12. The method of claim 11, wherein said FET is selected from the group consisting of a Metal-Oxide-Semiconductor Field Effect Transistor (MOSFET), a Metal-insulator-Semiconductor Field Effect Transistor, and a combination thereof.

13. The method of claim 11, wherein said high mobility semiconductor material is selected from the group consisting of Ge, SiGe, SiGeC, Ge alloys, GaAs, InAs, InP, group III-V compound semiconductors, and group II-VI compound semiconductors.

14. The method of claim 13, wherein said high mobility semiconductor material has about 10% to about 50% Ge.

15. The method of claim 11, wherein said low leakage semiconductor material is selected from the group consisting of Si, SiC, GaAs, InAs, InP, group III-V compound semiconductors, and group II-VI compound semiconductors.

16. The method of claim 11, wherein said FET is a short-channel MOSFET.

17. The method of claim 16, wherein said short-channel MOSFET has a channel with a length between about 5 nm and about 100 nm.

18. The method of claim 1, wherein said MOSFET is built on a substrate selected from the group consisting of a silicon substrate and a Silicon-On-Insulator substrate.

19. The method of claim 11, wherein said FET is selected from the group consisting of a n-type FET and p-type FET.

20. The method of claim 11, wherein said FET is an asymmetrical FET.
